(19) United States
(12) Patent Application Publication
(10) Pub. No.: US 2012/0025168 A1
(43) Pub. Date: Feb. 2, 2012

(54) STRAIN CONTROL IN SEMICONDUCTOR DEVICES

(75) Inventor: David John Wallis, Malvern (GB)

(73) Assignee: QINETIQ LIMITED, Farnborough, Hampshire (GB)

(21) Appl. No.: 13/263,663

(22) PCT Filed: Apr. 12, 2010
(86) PCT No.: PCT/GB2010/000737

§ 371 Date: Oct. 7, 2011

(30) Foreign Application Priority Data
Apr. 14, 2009 (GB) 0906331.4

(51) Int. Cl. H01L 29/06; H01L 21/20

(52) U.S. Cl. 257/18; 438/478; 257/E29.024; 257/E21.09

(57) ABSTRACT

A semiconductor device comprises the following elements: an active layer comprising a quantum well structure and a buffer layer beneath the active layer adapted to form a confinement layer for charge carriers in the active layer. The buffer layer is adapted so as not to increase an overall strain in the active layer. The active layer is already strained as a result of a lattice mismatch between the active layer and the buffer layer. Strain in the buffer layer may be controlled by use of a strain control buffer layer and by appropriate choices of material and composition for the buffer layer and for a substrate on which the buffer layer is grown.

### FIELD OF THE INVENTION

The invention relates to strain control in semiconductor devices. It is particularly relevant to strain control in semiconductor devices with a quantum well active layer, in particular QWFETs (Quantum Well Field Effect Transistors). It is relevant both to p-type and n-type devices.

### BACKGROUND TO THE INVENTION

In order to produce improvements to logic circuits, it is desirable to produce device structures, particularly field-effect transistors (FETs), that work at higher frequencies and lower powers. The standard architecture for digital circuit design is CMOS. To achieve CMOS circuits, both n-FETs (with electrons as charge carriers) and p-FETs (with holes as charge carriers) are required.

Conventional CMOS design is largely based on Si semiconductor technology. For n-FETs, very high operational frequencies and low operating powers have been achieved using InSb as a semiconductor. In this system, a layer of AlₓIn₁₋ₓ Sb is grown on a suitable substrate, such as GaAs, and a thin device layer of InSb grown over this. A donor layer to provide electrons is grown over the device layer, separated from it by a small AlₓIn₁₋ₓSb spacer layer. The device layer is capped by a suitable layer, again AlₓIn₁₋ₓSb, to confine the charge carriers in the device layer region, which forms a quantum well. For regions with a composition of AlₓIn₁₋ₓSb, the value of x may vary from region to region. There is a lattice mismatch between the InSb and the AlₓIn₁₋ₓSb, which can lead to strain in the quantum well which results in increased carrier mobility. InSb has a very high electron mobility, and extremely good results have been achieved.

Strained InSb quantum well structures have good hole mobility, and p-FETs with transconductance and cut-off frequency significantly higher than conventional Si or other III-V semiconductor systems have also been achieved. The useful thickness of a quantum well layer in a strained quantum well system is limited, as the lattice mismatch will eventually lead to creation of misfit dislocations at the boundary between the two layers to relieve the strain. The thickness at which this dislocation effect occurs can be predicted according to the model of Matthews and Blakeslee, set out in Journal of Crystal Growth Vol. 29 (1975) pp. 273-280 for a given lattice mismatch. For InSb quantum wells formed on a buffer layer of Al_{0.35}In_{0.65}Sb, this critical thickness is predicted to be 7 nm. However, it is found that in practice the hole mobility reduces once the thickness of a quantum well exceeds a significantly lower value—5 nm for an InSb well formed on a buffer layer of Al_{0.35}In_{0.65}Sb. Mobility is also reduced for very thin quantum wells as there are only a limited number of quantum states available, which has the effect of increasing effective carrier mass. It would therefore be desirable for the effective thickness of InSb quantum wells and other quantum well structures to be increased to the theoretical misfit dislocation limit and, if possible, beyond this.

### SUMMARY OF THE INVENTION

Accordingly, in a first aspect the invention provides a semiconductor device comprising: an active layer comprising a quantum well structure; a strain control buffer layer underneath and adjacent to the active layer; a main buffer layer underneath and adjacent to the strain control buffer layer; and a substrate underneath the main buffer layer; wherein the strain control buffer layer is formed such that the strain at the surface of the strain control buffer layer adjacent to the active layer is reduced with respect to the strain in the main buffer layer adjacent to the strain control active layer; and wherein the buffer layers form a confinement layer for charge carriers in the active layer.

This structure is highly advantageous, as it enables the active layer to be grown on a buffer layer which is—where adjacent to the active layer—essentially free of strain. Preferably, the strain in the strain control buffer layer is less than 0.1%, even less than 0.05%. This allows the thickness of the active layer to be greater than 5 nm.

Using this approach, the strain at the surface of the strain control buffer layer may be made opposite in sign to the strain in the main buffer layer adjacent to the strain control active layer. This can allow active layers to be constructed at greater thicknesses than is predicted by the Matthews & Blakeslee model.

By using a strain control buffer layer in conjunction with the main buffer layer, strain introduced due to thermal expansion mismatches between the substrate and buffer layer can be controlled.

In one arrangement, the active layer comprises a III-V semiconductor and the buffer layers comprise a ternary III-V material with a larger band gap. In a specifically described arrangement of this type, the III-V semiconductor is InSb and the ternary III-V material comprises AlₓIn₁₋ₓSb, where x varies between the strain control buffer layer and the main buffer layer. In this case x in the strain control buffer layer is greater than x in the main buffer layer. Preferably, x remains substantially constant within the strain control buffer layer (in other words, the strain control buffer layer is preferably not compositionally graded).

Other possible III-V semiconductor materials suitable for use in the invention are GaSb, InGaSb and AlGaSb.

The strain control buffer layer is sufficiently thin for strain to be frozen into it advantageously, this layer is less than 1 μm thick, even less than 0.6 μm thick in a preferred embodiment.

Such a device may advantageously be grown on GaAs or Si substrates.

Advantageously, the device may also comprise an upper confinement layer above the active layer. In the system described above, this may also be predominantly of Other layers may be present in the device, and may lie between the buffer layers and the active device. A dopant sheet may be formed to provide carriers for the active layer. This will typically be separated from the active layer only by a narrow spacer, which may for example be a thin layer of AlₓIn₁₋ₓSb. Such a dopant sheet may be formed either between buffer layer and active layer or between active layer and upper confinement layer.

The semiconductor device may be a precursor structure for a field-effect transistor, said structure comprising a substrate and epitaxially grown buffer and active layers as described herein. Optionally, the precursor structure may comprise a temporary or permanent cap layer, suitable capping materials being well known to the skilled person. The semiconductor device may further comprise a source, a drain and a gate to form a FET for which the active layer provides a conductive channel. Both n-FETs and p-FETs may be formed this way using the materials system described above.

In a further aspect, the invention provides a method of forming a semiconductor device, comprising: epitaxially growing a main buffer layer over a substrate; epitaxially growing a strain control buffer layer over the main buffer layer; epitaxially growing an active layer comprising a quantum well structure over the strain control buffer layer; and cooling the semiconductor device from a growth temperature for the buffer layers to an operating temperature, whereupon the strain at the surface of the strain control buffer layer adjacent to the active layer is reduced with respect to the strain in the main buffer layer adjacent to the strain control active layer; and wherein that the buffer layers form a confinement layer for charge carriers in the active layer.

Advantageously, the strain control buffer layer and the main buffer layer comprise the same ternary compound with different compositions. In one such arrangement, the strain control buffer layer and the main buffer layer comprise AlₓIn₁₋ₓSb with different values for x, and the active layer comprises an InSb quantum well structure.

In a still further aspect, the invention provides a semiconductor device comprising: an active layer comprising a quantum well structure; and a buffer layer underneath the active layer; wherein the active layer is strained by a lattice mismatch between the active layer and the buffer layer, and wherein the buffer layer adjacent to the active layer is adapted so as not to increase the strain in the active layer beyond the strain arising from the lattice mismatch.

The buffer layer adjacent to the active layer may be substantially unstrained, or it may be strained in an opposite sense to the strain in the active layer arising from the lattice mismatch, whereby an overall strain in the active layer is reduced.

Any feature in one aspect of the invention may be applied to any other aspects of the invention, in any appropriate combination. In particular device aspects may be applied to method aspects and vice versa. The invention extends to a device and method substantially as herein described, with reference to the accompanying drawings.

### SPECIFIC EMBODIMENTS OF THE INVENTION

Specific embodiments of the invention will now be described, by way of example, by reference to the accompanying Figures, of which:

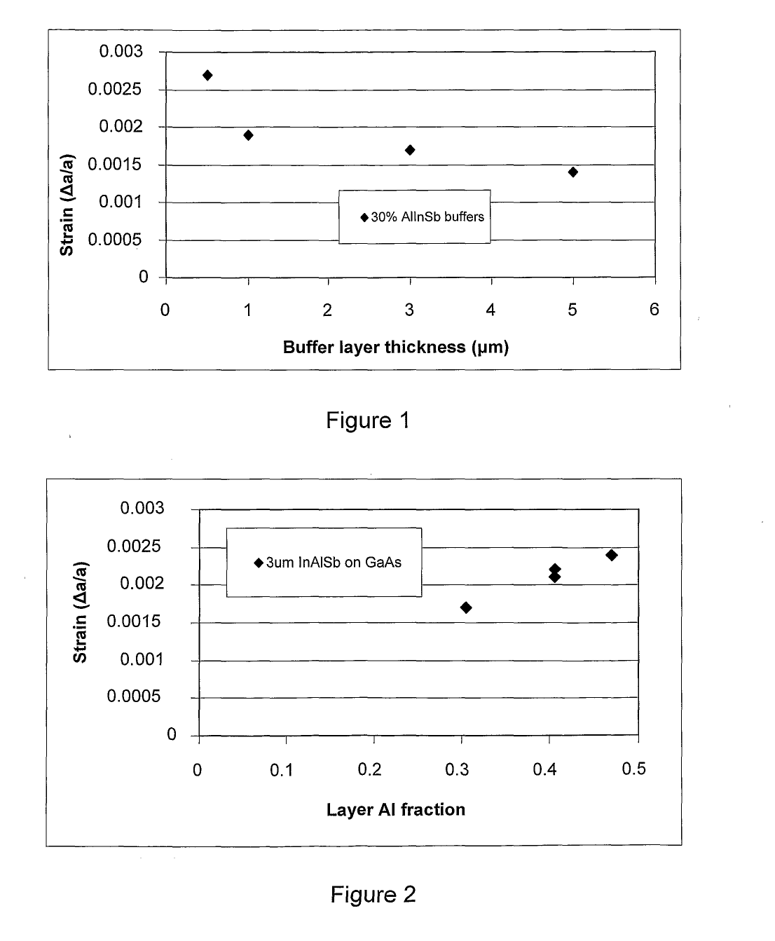

FIG. 1 illustrates variation in strain with layer thickness for Al_{0.3}In_{0.7}Sb buffer layers;

FIG. 2 illustrates variation in strain with Al fraction for AlInSb buffer layers grown on a GaAs substrate;

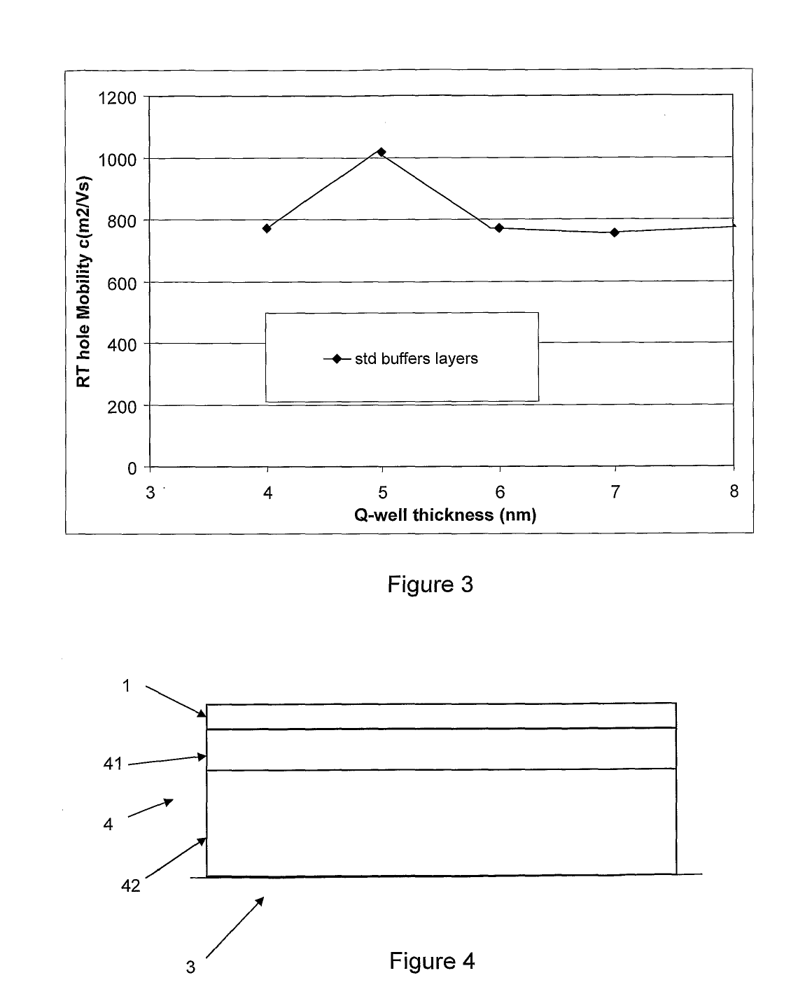

FIG. 3 illustrates variation in hole mobility for quantum well thickness for an InSb quantum well structure grown on a 3 μm thick Al_{0.35}In_{0.65}Sb buffer layer;

FIG. 4 shows a semiconductor device according to a first embodiment of the invention;

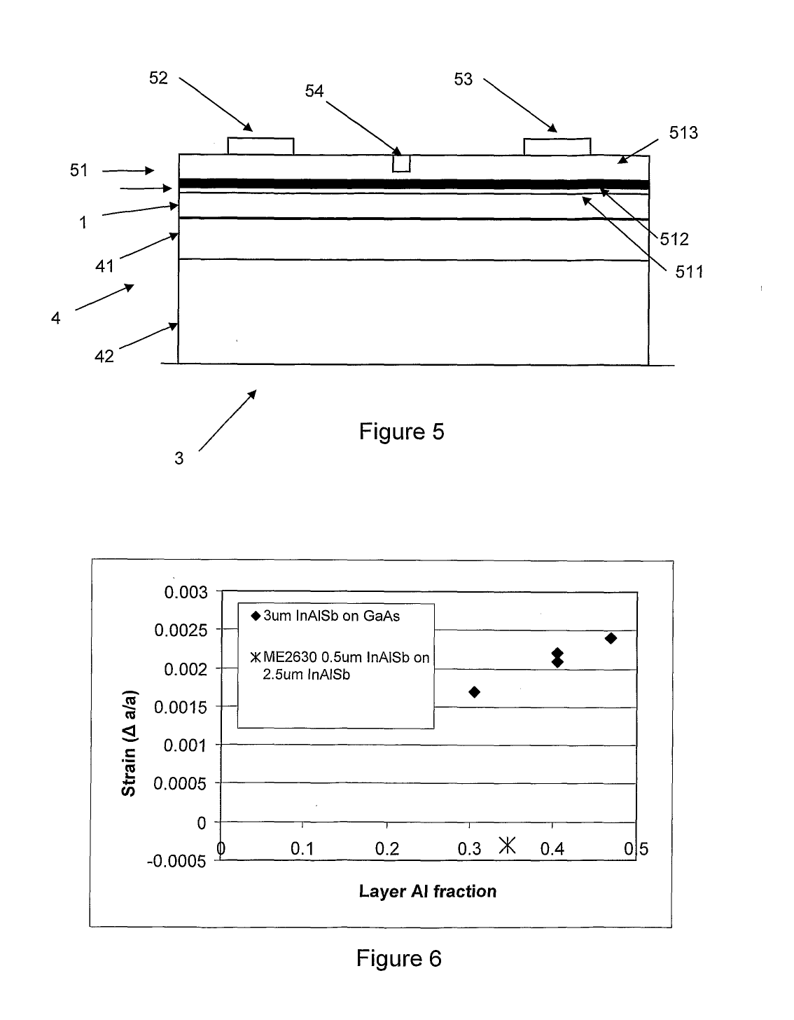

FIG. 5 shows the semiconductor device of FIG. 4 integrated into a p-FET;

FIG. 6 illustrates the strain in an exemplary semiconductor device of the type shown in FIG. 4 as compared to the buffer layers of FIG. 2;

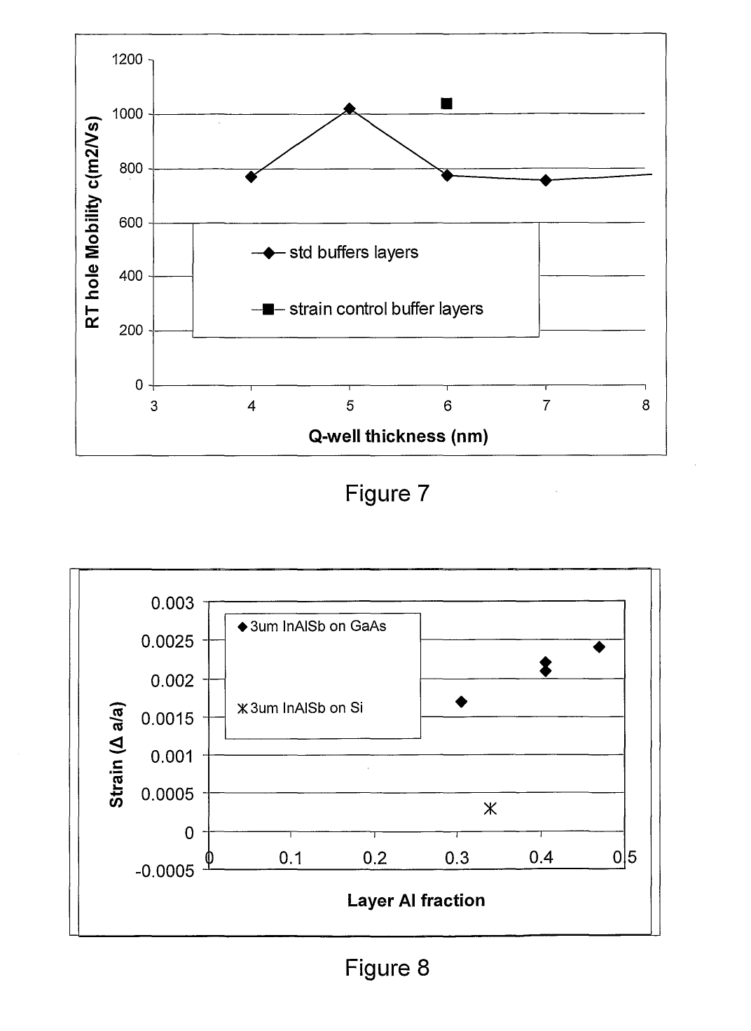

FIG. 7 illustrates the hole mobility in an exemplary semiconductor device of the type shown in FIG. 4 as compared to the buffer layers of FIG. 3;

FIG. 8 illustrates the strain in a 3 μm thick Al_{0.35}In_{0.65}Sb buffer layer grown on a Si substrate as compared to the buffer layers of FIG. 2; and

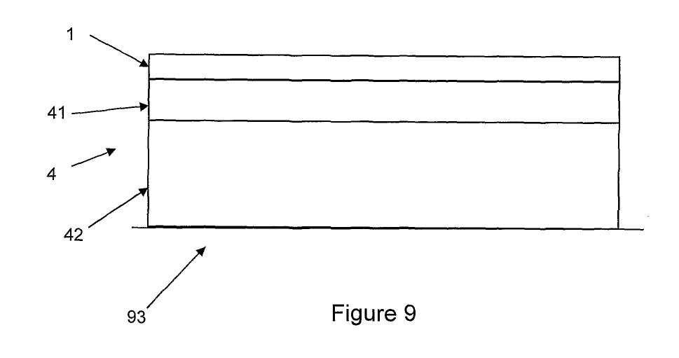

FIG. 9 shows a semiconductor device according to a second embodiment of the invention.

In order to show the benefit of embodiments of the invention, the properties of conventional buffer layers will now be discussed.

A conventional semiconductor device with a quantum well active layer contains the following main elements. The active layer comprises a layer of an appropriate semiconductor, such as InSb. This layer is a few nm thick, and is grown on a buffer layer of an appropriate material. This buffer layer is generally a semiconductor chosen to have a band gap which provides good confinement—the combination of this and other system properties achieves excellent carrier mobility in the active layer. A particularly suitable choice of buffer layer for InSb active layers is AlₓIn₁₋ₓ Sb, where the Al fraction (the value of x) may be varied to achieve different properties as desired. A similar AlₓIn₁₋ₓSb will generally be placed over the active layer as an upper confinement layer. The InSb layer is formed on the AlₓIn₁₋ₓSb buffer layer by an appropriate epitaxial growth technique, and the AlₓIn₁₋ₓSb layer is itself epitaxially grown on a suitable substrate—most normally GaAs or Si for this materials system. Molecular beam epitaxy (MBE) and metalorganic chemical vapour deposition (MOCVD) are particularly suitable epitaxial growth techniques, but any suitable growth technique may be used (other examples are MOVPE, ALD and MECVD). The buffer layer structure may itself contain further layers (such as a dopant sheet), as is discussed further below.

There is a significant lattice mismatch between InSb and AlₓIn₁₋ₓSb—both adopt a zincblende crystal structure, but the unit cell of the ternary compound is smaller, leading to a compressive strain on the active layer of approximately 2% for a value of x=0.35. This contributes to the excellent electrical properties of InSb quantum wells in this system—it leads to a valence and conduction band offset between InSb and AlₓIn₁₋ₓSb which results in very good confinement and excellent hole and electron mobility. This mismatch does however limit the thickness of active layer that can be achieved, as above a critical thickness of active layer formation of misfit dislocations will occur to relieve the misfit strain and hole mobility will be sharply reduced as a consequence. Using the model of Matthews and Blakeslee (as referenced above), this critical thickness is predicted to be 7 nm for an active layer of InSb on Al_{0.35}In_{0.65}Sb.

In practice, the present inventors find that there is another strain component to consider. There may also be strain in the buffer layer itself. While GaAs also adopts the zincblende crystal structure, there is again a significant lattice mismatch between the GaAs substrate and the AlₓIn₁₋ₓSb buffer layer. FIG. 1 shows experimental determination of strain in such a buffer layer with thickness for x=0.3. The significant lattice mismatch between GaAs and AlₓIn₁₋ₓSb leads to a high density of misfit dislocations and work hardening of the interface between the two. Work hardening is a known phenomenon in crystal growth, and refers to the immobilisation of dislocations by mutual pinning. This pinning prevents further relaxation of the crystal structure. This effect causes strain in the buffer layer which only relaxes fully at thicknesses of 1.5 μm and above, many times the critical thickness value.

However, as can be seen from FIG. 1, there is still strain present in the buffer layer even at thicknesses of 2 μm and above. This strain does not vary with thickness, and is not caused by lattice mismatch. This strain results from the different thermal expansion of GaAs and AlₓIn₁₋ₓSb. The thermal expansion coefficients of GaAs, InSb and AlSb are α_{GaAs}=5.4×10⁻⁶K⁻¹, α_{InSb}=5.6×10⁻⁶K⁻¹, and α_{AlSb}=4.3×10⁻⁶K⁻¹ respectively—in other words, the thermal expansion coefficients of GaAs and InSb are very similar, but that of AlSb is significantly smaller, with corresponding consequences for AlₓIn₁₋ₓSb. Epitaxial growth of AlₓIn₁₋ₓSb on GaAs typically takes place at a temperature of approximately 350° C. When the resulting structure is cooled to room temperature, the difference in thermal expansion coefficients between the two materials results in a strain component that does not vary significantly with the buffer layer thickness.

As is shown in FIG. 2, the strain resulting from the mismatch in thermal expansion coefficients increases with the fraction of Al in the buffer layer, as is consistent with the greater thermal expansion coefficient of AlSb. FIG. 2 shows the variation in strain with Al fraction for a 3 μm thick AlₓIn₁₋ₓSb buffer layer grown on a GaAs substrate. FIG. 2 suggests that there would be minimal thermal expansion strain in a buffer layer of InSb on GaAs, as could reasonably be expected given the similarity in thermal expansion coefficient between the two.

As shown in FIG. 3, hole mobility in the InSb quantum well structure declines above a critical thickness of 5 nm for the quantum well structure, rather than 7 nm as the Matthews and Blakeslee model predicts. The present inventors postulate that the reduction in critical thickness results from the thermal expansion strain in the AlₓIn₁₋ₓSb buffer layer.

The present inventors however also note that layers of AlₓIn₁₋ₓSb of less than 1 μm are unable to fully relax because of the work hardening phenomenon described above with reference to FIG. 1. Accordingly, a first embodiment of the invention has been devised, as is shown in FIG. 4. In this embodiment, the buffer layer 4 comprises a first buffer layer 41 and a second buffer layer 42. The second buffer layer 42 is grown on to the GaAs substrate 3 by an appropriate epitaxial process, and the first buffer layer 41 is grown over the second buffer layer 42 in a similar fashion. The InSb quantum well structure 2 is grown over the first buffer layer 41. Both the first and the second buffer layer are formed of AlₓIn₁₋ₓSb, but they have different Al fractions: x=0.35 for the first buffer layer, and x=0.3 for the second buffer layer.

FIG. 5 shows this basic device structure embodied in a p-channel FET. The elements identified in FIG. 4 are all present, but in addition to these there is an upper confinement layer 51 placed over the InSb quantum well structure 2. This upper layer is principally also of AlₓIn₁₋ₓSb (a suitable composition may again be Al_{0.35}In_{0.65}Sb, as for the first buffer layer 41), and is typically up to 20 nm thick—it needs to be sufficiently thick to provide adequate confinement of the charge carriers in the active layer, but sufficiently thin to allow the gate to control current flow in the channel effectively. The upper confinement layer 51 contains several sub-layers. Adjacent to the InSb quantum well structure 2 is a spacer layer 511—a suitable spacer layer would be a 3 nm thickness of Al_{0.35}In_{0.65}Sb. This separates the quantum well structure 2 from a dopant sheet 512 to provide carriers for the channel. For a p-channel, a suitable dopant sheet may use Be δdoping. The main upper confinement layer 513 is also formed from AlₓIn₁₋ₓSb—it may here also be in a composition of Al_{0.35}In_{0.65}Sb—and serves to confine charge carriers in the active layer. The source 52, the drain 53 and the gate 54 of the p-FET are provided by an appropriate metallisation process over the upper confinement layer 51. The main upper confinement layer 513 may be doped in appropriate locations to provide good electrical contact between the active layer and the source 52 and the drain 53, and the main upper confinement layer 513 may also be etched back in the region of the gate 54 to allow the gate 54 better effective control over the p-channel.

Alternatives to this structure are possible. For example, the dopant sheet may be formed in the strain control buffer layer instead of in the upper confinement layer—this will still allow for strain to be frozen in to the strain control buffer layer. While the example described here is for a p-FET with a p-channel, it should be noted that embodiments of the present invention may be constructed for an n-FET or another such device with an n-channel. Broadly the same structure may be employed for an n-FET, though different dopant would be employed (for example, a dopant sheet which uses Te δ-doping would be appropriate).

Further discussion of the fabrication and structure of InSb strained QWFETs can be found in the following papers. “High-Performance 40 nm Gate Length InSb p-Channel Compressively Strained Quantum Well Field Effect Transistors for Low-Power (V_{Cc}=0.5) Logic Applications”, by M. Radosavljevic et al, a paper presented to the 2008 IEEE International Electron Devices meeting (IEDB 2008) describes fabrication and structure of a p-FET. “InSb-based Quantum Well Transistors for High Speed, Low Power Applications” by T. Ashley et al, a paper presented to the 2005 Conference on Compound Semiconductor Manufacture (CS Mantech) describes fabrication and structure of an n-FET. The general principles set out in these documents concerning FETs using a strained quantum well active layer based on an InSb system are appropriate for use in embodiments of the present invention.

A typical fabrication process for this device would be as follows. The second, or main, buffer layer 42 is grown on the substrate 3 by an appropriate epitaxial growth technique such as MBE or MOCVD at an appropriate growth temperature (approximately 350° C. for AlₓIn₁₋ₓSb). The choice of growth temperature can be made according to established principles in this technical area (for example, AlₓIn₁₋ₓSb layers will generally be grown at higher temperatures with higher Al fraction, and layers will not be grown at temperatures which will damage layers already grown). The growth composition is modified, and the first, or strain control, buffer layer 41 is then grown over the second buffer layer 42 by the same process. A similar epitaxial growth process is then used for the InSb quantum well structure 2, before reverting to the conditions for growth of the first buffer layer 41 for growing the upper confinement layer 51. A conventional lithographic process, such as photolithographic masking or e-beam lithography and an etching process is then used to produce the metallisations above this, and so form the source 52, the drain 53 and the gate 54.

The effect of this two-layer buffer structure is to compensate for thermal expansion strain by building strain of opposite sign into the first buffer layer. This strain is introduced because of the lattice mismatch between Al_{0.35}In_{0.65}Sb and Al_{0.3}In_{0.7}Sb. As the Al_{0.35}In_{0.65}Sb layer is thin, it cannot fully relax, and so the strain is “frozen in”. The buffer layer is still fully effective to contain the charge carriers in the quantum well structure, but the portion of the buffer layer adjacent to the quantum well structure is now strain free. This is shown experimentally in FIG. 6, in which the strain in the first buffer layer 41 of the structure of FIG. 4 is shown in comparison to the data shown in FIG. 2. As can be seen in FIG. 6, the resulting strain is under 0.05%, as opposed to a strain of 0.2% for a conventional Al_{0.35}In_{0.65}Sb buffer layer. The strain is also of opposite sign, as in this case the frozen-in strain more than compensates for the thermal expansion strain—appropriate variation of thickness or composition can reduce this strain further, or make the value more negative, as desired.

FIG. 7 shows the observed effect of the removal of strain from the buffer layer adjacent to the active layer. This figure shows the hole mobility in the two-layer buffer of FIG. 4, in which the first buffer layer 41 is essentially strain free, in comparison to conventional buffer layers (as shown in FIG. 3). It can be seen that the critical thickness of the active layer is increased closer to the limit predicted by the Matthews and Blakeslee model—the hole mobility at 6 nm has the same value as found at 5 nm for a conventional buffer layer. For a conventional buffer layer, the maximum hole mobility is reached at 5 nm active layer thickness, after which the hole mobility declines as a result of the dislocations arising from the thermal expansion strain.

This arrangement is beneficial, as increasing the active layer thickness without loss of hole mobility provides improved electrical properties. Increasing active layer thickness increases capacity of the quantum well and may increase mobility of the carriers. Number of carriers and mobility together influence the current that the device can handle, and carrier mobility is related to the device speed. Increasing quantum well thickness may also improve device reliability, as devices with a thicker quantum well will be less likely to generate defects during operation.

Further benefits may also be attainable. As noted above, the strain in the first buffer layer may not only be reduced to be strain-free, but may in fact be “reduced” still further by overcompensating for thermal expansion strain (for example, by using a narrower first buffer layer with more frozen-in strain) to produce a first buffer layer with opposite strain. This allows the active layer to be grown beyond the critical thickness without loss of mobility, as this oppositely-signed strain would relieve the mismatch strain sufficiently to prevent formation of dislocations until a greater thickness was reached.

Where there is a lower thermal expansion coefficient substrate, then less strain needs to be frozen in to the first buffer layer. FIG. 8 shows the strain in a buffer layer of 3 μm of Al_{0.35}In_{0.65}Sb grown on a Si substrate comparison to the data shown in FIG. 2. Si has a thermal expansion coefficient of 2.6×10⁻⁶K⁻¹, resulting in much lower strain in conventional buffer layers. This means that using the buffer layer structure of FIG. 4 will result in strain of opposite sign in the buffer layer adjacent to the active layer, with the possibility of increasing the quantum well thickness above the Matthews and Blakeslee limit as described above—this is illustrated in FIG. 9, which shows the same structure as for FIG. 4 but replacing the GaAs substrate with a Si substrate 93. A similar effect may be achieved by using different composition layers in the buffer to adjust thermal expansion related strain. These effects may be used cumulatively, allowing for the possibility of a significant compensating strain in the buffer layer at the interface with the quantum well, and hence the possibility of a significant increase in quantum well thickness beyond the calculated Matthews and Blakeslee limit.

The embodiments described above relate to growth of InSb on AlInSb buffer layers grown on GaAs or Si substrates, but other embodiments can be developed appropriate to other semiconductor systems. The same principles may clearly be applied to any III-V semiconductor system using ternary buffer layers, with suitable modifications of the structure to take account of lattice parameters, elastic constants and thermal expansion coefficients. For example, this approach could be applied to a system using α-Sn as semiconductor, rather than InSb (as is discussed in the applicant's British patent application GB 0906336.3 and the co-pending PCT application of even date entitled “P-Type Semiconductor Devices”, which is incorporated by reference herein to the extent permitted by law). Application of these principles is not limited to III-V systems—these principles may also be applied to V-V and II-VI semiconductor systems at least. The principles discussed here may also be used with other approaches to improve electrical properties of a device by adjusting strain, for example as discussed in the applicant's British patent application GB 0906333.0 and the co-pending PCT application of even date entitled “Uniaxial Tensile Strain in Semiconductor Devices”, which is incorporated by reference herein to the extent permitted by law.

1. A semiconductor device comprising:
an active layer comprising a quantum well structure;
a strain control buffer layer underneath to the active layer;
a main buffer layer underneath and adjacent to the strain control buffer layer; and
a substrate underneath the main buffer layer;
wherein the strain control buffer layer is formed such that the strain at the surface of the strain control buffer layer adjacent to the active layer is reduced with respect to the strain in the main buffer layer adjacent to the strain control active layer; and wherein the buffer layers form a confinement layer for charge carriers in the active layer.

2. A semiconductor device as claimed in claim 1, wherein the thickness of the active layer is greater than 5 nm.

3. A semiconductor device as claimed in claim 1, wherein the strain in the strain control buffer layer is less than 0.1%.

4. A semiconductor device as claimed in claim 3, wherein the strain in the strain control buffer layer is less than 0.05%.

5. A semiconductor device as claimed in claim 1, wherein the strain at the surface of the strain control buffer layer is opposite in sign to the strain in the main buffer layer adjacent to the strain control active layer; and wherein an overall strain in the active layer is reduced thereby.

6. A semiconductor device as claimed in claim 1, wherein the active layer comprises a III-V semiconductor and the buffer layers comprise a ternary III-V insulator material.

7. A semiconductor device as claimed in claim 6, wherein the III-V semiconductor is InSb and the ternary 111-V insulator material comprises AlₓIn₁₋ₓSb, where x varies between the strain control buffer layer and the main buffer layer.

8. A semiconductor device as claimed in claim 7, where x in the strain control buffer layer is greater than x in the main buffer layer.

9. A semiconductor device as claimed in claim 1, where the strain control buffer layer is less than 1 μm thick.

10. A semiconductor device as claimed in any claim 1, where the strain control buffer layer is less than 0.6 μm thick.

11. A semiconductor device as claimed in claim 1 wherein the substrate comprises GaAs.

12. A semiconductor device as claimed in claim 1 wherein the substrate comprises Si.

13. A semiconductor device as claimed in claim 1, wherein the semiconductor device comprises an upper confinement layer above the active layer.

14. A semiconductor device as claimed in claim 1, wherein the semiconductor device further comprises a dopant sheet to provide carriers for the active layer.

15. A semiconductor device as claimed in claim 14, wherein the dopant sheet is provided between the strain control buffer layer and the active layer.

16. A semiconductor device as claimed in claim 1 and further comprising a source, a drain and a gate to form a FET for which the active layer provides a conductive channel.

17. A method of forming a semiconductor device, comprising:
epitaxially growing a main buffer layer over a substrate;
epitaxially growing a strain control buffer layer over the main buffer layer; and
epitaxially growing an active layer comprising a quantum well structure over the strain control buffer layer; and
cooling the semiconductor device from a growth temperature for the buffer layers to an operating temperature, whereupon the strain at the surface of the strain control buffer layer adjacent to the active layer is reduced with respect to the strain in the main buffer layer adjacent to the strain control active layer; and wherein the buffer layers form a confinement layer for charge carriers in the active layer.

18. A method as claimed in claim 17, wherein the main control layer and the buffer control layer comprise the same ternary compound with different compositions.

19. A method as claimed in claim 18, wherein the main control layer and the buffer control layer comprise AlₓIn₁₋ₓSb with different values for x, and wherein the active layer comprises an InSb quantum well structure.

20. A semiconductor device comprising:
an active layer comprising a quantum well structure; and
a buffer layer underneath the active layer;
wherein the active layer is strained by a lattice mismatch between the active layer and the buffer layer, and wherein the buffer layer adjacent to the active layer is adapted so as not to increase the strain in the active layer beyond the strain arising from the lattice mismatch.

21. A semiconductor device as claimed in claim 20, wherein the buffer layer adjacent to the active layer is substantially unstrained.

22. A semiconductor device as claimed in claim 20, wherein the buffer layer adjacent to the active layer is strained in an opposite sense to the strain in the active layer arising from the lattice mismatch, whereby an overall strain in the active layer is reduced.

23-24. (canceled)
